(19) United States
(12) Patent Application Publication
(10) Pub. No.: US 2016/0020232 A1
(43) Pub. Date: Jan. 21, 2016

(54) SOLID STATE IMAGING DEVICE AND METHOD FOR MANUFACTURING SAME

(71) Applicant: KABUSHIKI KAISHA TOSHIBA, Tokyo (JP)

(72) Inventors: Hiroyuki FUKUMIZU, Yokohama (JP); Rikyu IKARIYAMA, Chigasaki (JP)

(73) Assignee: KABUSHIKI KAISHA TOSHIBA, Tokyo (JP)

(21) Appl. No.: 14/797,257

(22) Filed: Jul. 13, 2015

(30) Foreign Application Priority Data
Jul. 17, 2014 (JP) 2014-146591

(51) Int. Cl. H01L 27/146; G02B 1/113; G02B 1/16

(52) U.S. Cl. CPC H01L 27/1462; G02B 1/16; G02B 1/113; H01L 27/14685

(57) ABSTRACT

According to one embodiment, a solid state imaging device includes a semiconductor layer and an anti-reflection film. The semiconductor layer performs photoelectric conversion. The anti-reflection film is provided on the semiconductor layer. The anti-reflection film is conductive.

### CROSS REFERENCE TO RELATED APPLICATIONS

This application is based upon and claims the benefit of priority from the Japanese Patent Application No. 2014-146591, filed on Jul. 17, 2014; the entire contents of which are incorporated herein by reference.

### FIELD

Embodiments described herein relate generally to a solid state imaging device and a method for manufacturing same.

### BACKGROUND

A solid state imaging device that includes a photoelectric conversion element provided on a semiconductor substrate is utilized in CCD (Charge-Coupled Device) image sensors, CMOS (Complementary Metal-Oxide Semiconductor) image sensors, etc.

Solid state imaging devices are broadly divided into two types, i.e., a front-side illuminated type and a back-side illuminated type. The front-side illuminated solid state imaging device has a structure in which light is received from the semiconductor substrate front surface side where the signal read-out circuit, etc., are formed. The back-side illuminated solid state imaging device has a structure in which light is received from the surface on the side opposite to the semiconductor substrate front surface. Downscaling of the pixels progresses as the number of pixels increases; and it is desirable to improve the display quality of the solid state imaging device having such a structure,

### BRIEF DESCRIPTION OF THE DRAWINGS

FIG. 1 is a schematic cross-sectional view showing a solid state imaging device according to the embodiment;

FIG. 2 shows a characteristic of the solid state imaging device according to the embodiment; and

FIG. 3A to FIG. 3E are a flowchart of some of the manufacturing processes of the solid state imaging device.

### DETAILED DESCRIPTION

According to one embodiment, a solid state imaging device includes a semiconductor layer and an anti-reflection film. The semiconductor layer performs photoelectric conversion. The anti-reflection film is provided on the semiconductor layer. The anti-reflection film is conductive.

An embodiment of the invention will now be described with reference to the drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

In the specification of the application, being “provided on” includes not only the case of being provided in direct contact but also the case of being provided with another layer or film inserted therebetween.

### Embodiment

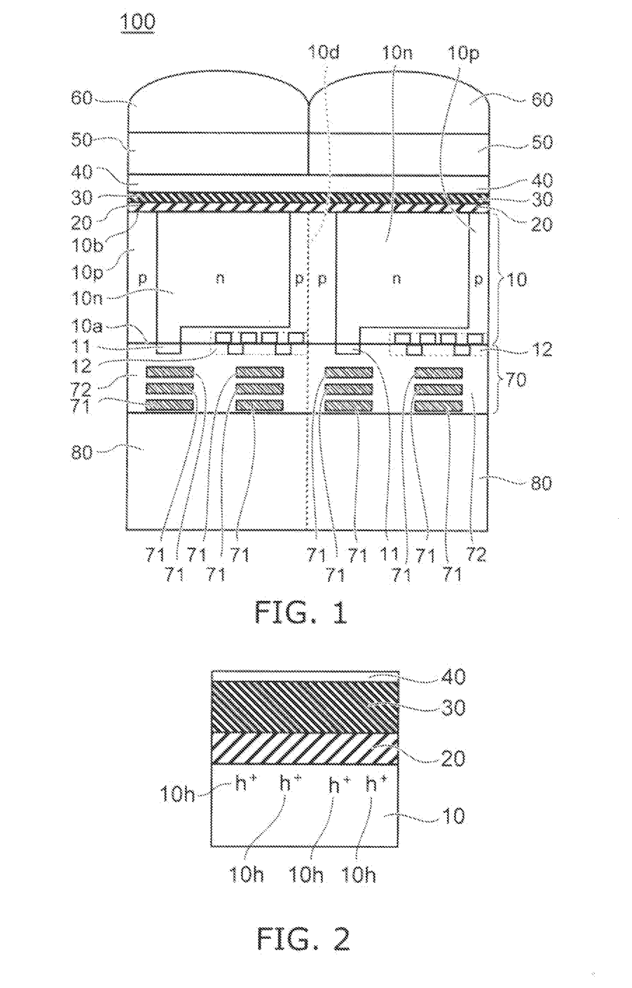

FIG. 1 is a schematic cross-sectional view showing a solid state imaging device according to the embodiment.

FIG. 2 shows a characteristic of the solid state imaging device according to the embodiment.

FIG. 1 is a cross-sectional view of a pixel region of the solid state imaging device. A portion of the solid state imaging device of the embodiment is shown in FIG. 2.

As shown in FIG. 1, a semiconductor layer 10, an oxide film 20, an anti-reflection film 30, a planarization film 40, color filters 50, microlenses 60, an interconnect layer 70, and a support substrate 80 are provided in the solid state imaging device 100.

The semiconductor layer 10 has a first surface 10a and a second surface 10b. The first surface 10a is the surface on the side opposite to the second surface 10b. In the embodiment, the first surface 10a is the front surface; and the second surface 10b is the back surface. The solid state imaging device 100 of the embodiment is a back-side illuminated solid state imaging device.

The oxide film 20 is, for example, a film including a silicon oxide such as silicon dioxide (SiO₂), etc. The oxide film 20 is provided on the second surface 10b of the semiconductor layer 10. In the case where the semiconductor layer 10 includes silicon (Si) and the oxide film 20 includes silicon oxide, dark current may occur due to the interface state at the interface between the silicon and the silicon oxide. A film that includes a negative fixed charge may be provided on the oxide film 20 to suppress the occurrence of the dark current. For example, hafnium oxide (HfOₓ) or a stacked film of hafnium oxide and silicon dioxide is used as such a fixed charge film.

The anti-reflection film 30 is provided on the oxide film 20. The light amount that is incident on the semiconductor layer 10 is increased by providing the anti-reflection film 30. The sensitivity of the pixels can be increased by increasing the light amount that is incident on the semiconductor layer 10. The film thickness of the anti-reflection film 30 is not less than 20 nanometers and not more than 100 nanometers.

The anti-reflection film 30 includes silicon nitride (SiN), silicon oxynitride (SiON), a tantalum compound, or a titanium compound. The anti-reflection film 30 may include at least one of these materials. Tantalum oxide (Ta₂O₅) may be used as the tantalum compound. Titanium oxide (TiO₂) may be used as the titanium compound.

The anti-reflection film 30 has a refractive index of not less than 2.0 and not more than 3.0. For example, the refractive index of silicon oxide for light of a wavelength of 633 nanometers is 1.5. The refractive index of tantalum oxide for light of a wavelength of 633 nanometers is 2.1. For light of a wavelength of 633 nanometers, the refractive index of tantalum oxide is higher than the refractive index of silicon oxide. The sensitivity of the pixels can be increased by using a film having a refractive index of 2.0 or more as the anti-reflection film 30. A stacked film that includes a film having a refractive index of 2.0 or more may be used as the anti-reflection film 30.

The anti-reflection film 30 includes at least one of niobium (Nb), tantalum (Ta), or tungsten (W). The anti-reflection film 30 is provided with conductivity by doping the anti-reflection film 30 with at least one of niobium, tantalum, or tungsten. The anti-reflection film 30 is both a conductive film and a film that increases the light amount that is incident on the semiconductor layer 10. For example, the amount of the niobium or the tantalum contained in the anti-reflection film 30 is 10 atom % or less.

For example, as the anti-reflection film 30, a film that includes titanium oxide (TiO₂) is doped with niobium. The titanium oxide film is insulative. The anti-reflection film 30 functions as a semiconductor by doping the titanium oxide film with niobium.

A negative voltage is applied to the anti-reflection film 30. For example, the negative voltage is applied to the anti-reflection film 30 by a voltage application unit (not shown) provided outside the solid state imaging device 100. The voltage application unit includes a circuit of a power supply, a switching element, etc. When the negative voltage is applied to the anti-reflection film 30, holes are generated at the interface between the semiconductor layer 10 including silicon and the oxide film 20 including silicon oxide. The anti-reflection film 30 may be grounded to generate the holes at the interface between the semiconductor layer 10 and the oxide film 20.

The planarization film 40 planarizes the surface where the color filters 50 are formed. The planarization film 40 is provided on the anti-reflection film 30.

The color filters 50 transmit light of different wavelength regions. The color filters 50 are provided on the planarization film 40. The color filters 50 include, for example, an R color filter that transmits light of the red wavelength region, a G color filter that transmits light of the green wavelength region, and a 8 color filter that transmits light of the blue wavelength region.

The microlenses 60 condense light that is incident from the light source and guide the light toward the second surface 10b (the back surface) side of the semiconductor layer 10. The microlenses 60 are provided on the color filters 50.

The interconnect layer 70 is provided on the first surface 10a of the semiconductor layer 10. The interconnect layer 70 includes multilayer interconnects 71 and an inter-layer insulating layer 72. The multilayer interconnects 71 are formed inside the inter-layer insulating layer 72. The support substrate 80 is provided on the interconnect layer 70.

The semiconductor layer 10 is an epitaxial layer formed on a semiconductor substrate such as a silicon substrate, etc. The semiconductor layer 10 includes an n-type diffusion layer 10n and a p-type region 10p. The film thickness of the semiconductor layer 10 is, for example, about 4 micrometers.

A transfer transistor 11 and a transistor group 12 are provided at the boundary vicinity of the semiconductor layer 10 and the interconnect layer 70. The transistor group 12 includes, for example, an amplifier transistor, a reset transistor, and an address transistor.

Photoelectric conversion is performed by the n-type diffusion layer 10n and the p-type region 10p. That is, signal conversion of the light that is irradiated from the microlens 60 toward the semiconductor layer 10 is performed; and a charge is stored. The n-type diffusion layer 10n stores signal electrons generated by the photoelectric conversion. The transfer transistor 11 moves the signal electrons stored in the n-type diffusion layer 10n to a diffusion layer, etc. The amplifier transistor that is connected to the diffusion layer, etc., amplifies the signal electrons and outputs the signal electrons to the multilayer interconnects 71. The address transistor controls the timing of the output of the signal electrons by the amplifier transistor. The reset transistor controls the amplifier transistor to be in the initial state.

The region that is formed from the n-type diffusion layer 10n and the p-type region 10p corresponds to the pixels. A separation layer may be provided between pixels (a dotted line portion 10d). Color mixing of the photoelectrons between pixels is suppressed by the separation layer. Also, the sensitivity of the pixels can be increased by forming the separation layer from a reflective material.

There is a stacked body that includes an oxide film, an anti-reflection film, a planarization film, color filters, and microlenses provided on a semiconductor layer. Dark current may occur due to the interface state at the interface between the semiconductor layer and the oxide film. When the back surface of the semiconductor layer is patterned to any thickness, a defect state occurs in the surface of the silicon; and the dark current and white blemishes occur. The dark current and the white blemishes increase because such a stacked body is formed on the backside by reactive ion etching (RIE) and film formation processes using plasma CVD (Plasma-Enhanced Chemical Vapor Deposition).

The dark current is the leakage current that flows in the solid state imaging device when there is no light. The white blemishes are defects that occur due to the leakage current.

To suppress the occurrence of the dark current and the white blemishes, there is a method for providing a semiconductor layer that includes silicon, an oxide film that includes silicon oxide, and a p-type intermediate layer directly under the interface between the semiconductor layer and the oxide film. A positive charge is stored in the intermediate layer by providing the intermediate layer. In the case where a region that stores a positive charge such as an intermediate layer, etc., is provided at the back surface of the semiconductor layer, it is necessary to implant an impurity into the semiconductor layer from the backside and activate the impurity. Also, it is necessary to perform annealing of the crystal defects that occur when implanting the impurity.

However, interconnect layers of copper (Cu), aluminum (Al), etc., are provided at the front surface of the semiconductor layer in a back-side illuminated solid state imaging device. Accordingly, it is difficult to form a region that stores a positive charge at the back surface of the solid state imaging device because temperature constraints arise for the annealing for which high temperature heat treatment is necessary. That is, it is difficult to form a region that stores a positive charge using such a method and reduce the dark current.

On the other hand, in the solid state imaging device 100 of the embodiment, the anti-reflection film 30 that is conductive is provided on the second surface 10b (the back surface) of the semiconductor layer 10 where the photoelectric conversion is performed. Also, a negative voltage is applied to the anti-reflection film 30; and the refractive index of the anti-reflection film 30 is not less than 2.0 and not more than 3.0. The dark current and the white blemishes can be reduced by forming such an anti-reflection film 30.

By forming the anti-reflection film 30 that is conductive, not only the pixels but also components other than the pixels have the same potential; and therefore, the damage due to plasma CVD, reactive ion etching, and ashing and the electric field concentration due to the charge are relaxed. Accordingly, the dark current and the white blemishes decrease.

As shown in FIG. 2, the anti-reflection film 30 to which the negative voltage is applied is formed on the oxide film 20. Holes 10h can be stored at the interface between the semiconductor layer 10 and the oxide film 20, That is, the region that stores the positive charge is formed from the holes 10h. The holes 10h that are stored recombine with the electrons (the dark electrons) that cause the dark current at the interface between the semiconductor layer 10 and the oxide film 20; the dark electrons disappear; and the occurrence of the dark current is suppressed.

According to the embodiment, a solid state imaging device having good characteristics is provided.

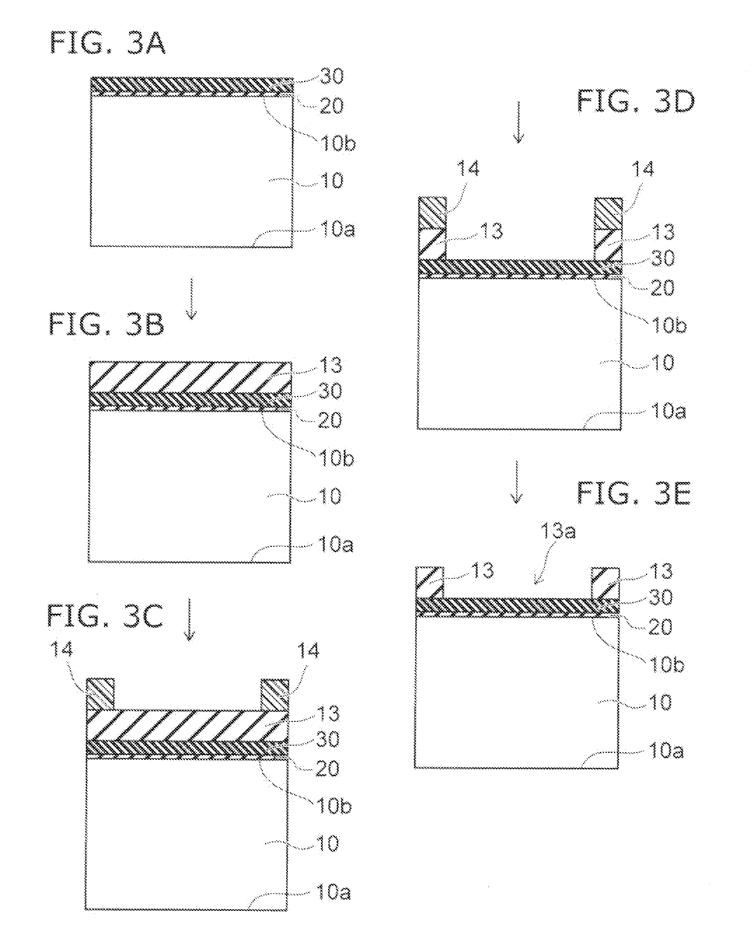

FIG. 3A to FIG. 3E are a flowchart of some of the manufacturing processes of the solid state imaging device.

FIG. 3A to FIG. 3E are cross-sectional views of the pixel region of the solid state imaging device.

As shown in FIG. 3A, the anti-reflection film 30 is formed on the oxide film 20 that is provided on the second surface 10b of the semiconductor layer 10 where the photoelectric conversion is performed.

As the anti-reflection film 30, a film that includes titanium oxide (TiO₂) is doped with niobium (Nb). A TiO₂ film that is doped with 5% niobium is formed by sputtering. Annealing is performed for the Nb—TiO₂ film that is formed. The annealing is performed for about 1 hour at a temperature of 400° C. The resistance of the Nb—TiO₂ film is reduced by performing the annealing of the Nb—TiO₂ film. For example, the sheet resistance of the Nb—TiO₂ film is about 0.014 ohm·centimeter; and the thickness of the Nb—TiO₂ film is about 50 nanometers.

The anti-reflection film 30 is provided with conductivity by being doped with niobium. For example, the dark current is 20 (an arbitrary multiplier) for a solid state imaging device that includes a TiO₂ film not doped with niobium. On the other hand, the dark current is 10 (an arbitrary multiplier) for a solid state imaging device that includes the Nb—TiO₂ film. It can be seen that the dark current decreases for the solid state imaging device in which the Nb—TiO₂ film is provided.

Also, the negative voltage is applied to the anti-reflection film 30. The dark current is 2 (an arbitrary multiplier) for a solid state imaging device that includes the Nb—TiO₂ film to which the negative voltage (−2 V) is applied. It can be seen that the dark current decreases for the solid state imaging device that includes the Nb—TiO₂ film to which the negative voltage is applied.

A fixed charge film may he provided between the oxide film 20 and the anti-reflection film 30. By forming the film between the semiconductor layer 10 and the anti-reflection film 30, the anti-reflection film 30 that is conductive is electrically insulated from the semiconductor layer 10 that includes silicon.

As shown in FIG. 3B, an inter-layer insulating film 13 is formed on the anti-reflection film 30. For example, the inter-layer insulating film 13 includes a silicon oxide such as silicon dioxide, etc.

As shown in FIG. 3C, a resist 14 is formed on the inter-layer insulating film 13 as a mask in which the pixel region is exposed.

As shown in FIG. 3D, a portion of the inter-layer insulating film 13 is removed by dry etching or wet etching using the resist 14 as a mask.

As shown in FIG. 3E, the resist 14 is removed. Subsequently, the planarization film 40, the color filters 50, and the microlenses 60 are formed on the anti-reflection film 30 in an opening 13a provided between the inter-layer insulating film 13. The opening 13a corresponds to the pixel region. For example, a circuit region is formed at the periphery of the pixel region.

The oxide film 20, the anti-reflection film 30, the planarization film 40, the color filters 50, the microlenses 60, etc., can be formed using CVD (Chemical Vapor Deposition), coating, PVD (Physical Vapor Deposition) including sputtering or vacuum vapor deposition, ALD (Atomic Layer Deposition), and/or reactive ion etching.

According to the embodiment, a method for manufacturing a solid state imaging device having good characteristics is provided.

Hereinabove, embodiments of the invention are described with reference to specific examples. However, the invention is not limited to these specific examples. For example, one skilled in the art may similarly practice the invention by appropriately selecting specific configurations of components such as the semiconductor layer, the oxide film, the anti-reflection film, the planarization film, the color filters, the microlenses, the interconnect layer, the support substrate and the inter-layer insulating film, etc., from known art; and such practice is within the scope of the invention to the extent that similar effects can be obtained.

Moreover, combinations of two or more components in the specific examples within a technically feasible range are also included in the scope of the invention as long as the spirit of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can he combined mutually and can be carried out.

What is claimed is:

1. A solid state imaging device, comprising:
a semiconductor layer performing photoelectric conversion; and
an anti-reflection film provided on the semiconductor layer, the anti-reflection film being conductive.

2. The device according to claim 1, wherein a refractive index of the anti-reflection film is not less than 2.0 and not more than 3.0.

3. The device according to claim 1, wherein the anti-reflection film includes at least one of titanium or oxygen.

4. The device according to claim 1, wherein the anti-reflection film includes at least one of titanium oxide or tantalum oxide.

5. The device according to claim 1, wherein the anti-reflection film includes at least one of niobium, tantalum, or tungsten.

6. The device according to claim 1, wherein
the anti-reflection film includes at least one of niobium or tantalum, and
the amount of the niobium or the tantalum contained in the anti-reflection film is 10 atom % or less.

7. The device according to claim 1, wherein the anti-reflection film is grounded.

8. The device according to claim 1, further comprising an oxide film provided between the semiconductor layer and the anti-reflection film.

9. The device according to claim 1, wherein a film thickness of the anti-reflection film is not less than 20 nanometers and not more than 100 nanometers.

10. A method for manufacturing a solid state imaging device, comprising:
forming an oxide film on a semiconductor layer, the semiconductor layer performing photoelectric conversion; and
forming an anti-reflection film on the oxide film, the anti-reflection film being conductive.

11. The method according to claim 10, wherein a refractive index of the anti-reflection film is not less than 2.0 and not more than 3.0.

12. The method according to claim 10, wherein the anti-reflection film includes at least one of titanium or oxygen.

13. The method according to claim 10, wherein the anti-reflection film includes at least one of titanium oxide or tantalum oxide.

14. The method according to claim 10, wherein the anti-reflection film includes at least one of niobium, tantalum, or tungsten.

15. The method according to claim 10, wherein
the anti-reflection film includes at least one of niobium or tantalum, and
the amount of the niobium or the tantalum contained in the anti-reflection film is 10 atom % or less.

16. The method according to claim 10, further comprising applying a negative voltage to the anti-reflection film.

17. A method for manufacturing a solid state imaging device, comprising:
forming an oxide film on a semiconductor layer, the semiconductor layer performing photoelectric conversion;
forming an anti-reflection film on the oxide film, the anti-reflection film including at least one of titanium or oxygen; and
doping the anti-reflection film with a metal.

18. The method according to claim 17, wherein the anti-reflection film includes at least one of titanium oxide or tantalum oxide.

19. The method according to claim 17, wherein the metal is at least one of niobium, tantalum, or tungsten.

20. The method according to claim 17, further comprising applying a negative voltage to the anti-reflection film.
